(19) United States
(12) Patent Application Publication
(10) Pub. No.: US 2025/0212363 A1
(43) Pub. Date: Jun. 26, 2025

(54) WATER BLOCK STRUCTURE

(71) Applicant: Ming-Hung CHEN, New Taipei City (TW)

(72) Inventor: Ming-Hung CHEN, New Taipei City (TW)

(21) Appl. No.: 18/391,594

(22) Filed: Dec. 20, 2023

(51) Int. Cl. H05K 7/20

(52) U.S. Cl. CPC H05K 7/20263

(57) ABSTRACT

A heat sink structure includes a seat, multiple fins and a cover body. The seat includes a bottom plate and an annular peripheral plate upward extended from the bottom plate. An accommodation space recessed on the seat is enclosed by the bottom plate and the annular peripheral plate. The fins are disposed in the accommodation space. The cover body correspondingly covers the seat and is screwed to the annular peripheral plate. Thereby, the heat sink structure has great cooling efficiency.

### BACKGROUND

### Technical Field

The disclosure relates to a liquid-cooling device, particularly to a heat sink structure.

### Related Art

Water blocks have been widely used in the field of water-cooling heat dissipation, which include a shell and a plurality of cooling fins. The shell is sealed and has a chamber. When the working fluid flows through each cooling fin, the heat carried by it will be transferred to each cooling fin for heat dissipation, thereby effectively reducing the temperature of the working fluid and achieving a cooling effect.

Since the shell must be sealed and a plurality of cooling fins must be installed in the chamber, most shells in the market are designed to be two-piece or multi-piece to facilitate manufacturing. The multiple cooling fins are welded and fixed on one of the shells first, and then the multiple shells are welded and fixed together to form a water block.

However, when the multiple shells are welded together, solder and flux must be used. However, since the solder and flux are made of different materials, and the shell is made of a different material from the aforementioned both, the thermal resistance of each welding joint of the water block will increase, which affects the cooling efficiency of the water block.

In view of this, the inventors have devoted themselves to the above-mentioned prior art, researched intensively and cooperated with the application of science to try to solve the above-mentioned problems. Finally, the invention which is reasonable and effective to overcome the above drawbacks is provided.

### SUMMARY

The disclosure is to provide a water block, which uses the cover body that correspondingly covers the seat and is screwed to the annular peripheral plate to achieve the water block having great cooling efficiency.

In an embodiment of the disclosure, the disclosure provides a heat sink structure, which includes a seat, multiple fins and a cover body. The seat includes a bottom plate and an annular peripheral plate upward extended from the bottom plate. An accommodation space recessed on the seat is enclosed by the bottom plate and the annular peripheral plate jointly define. The fins are disposed in the accommodation space. The cover body correspondingly covers the seat and is screwed to the annular peripheral plate.

Accordingly, the cover body correspondingly covers the seat and is screwed to the annular peripheral plate to prevent solder or flux for welding from causing a water block having different materials, so as to omit the condition of increase of the thermal resistance at the place of different materials to achieve the improvement of the cooling efficiency of the heat sink structure.

Accordingly, the first O-ring is disposed at a junction of the annular peripheral plate and the cover body which is at an outside of the annular peripheral plate, and the second O-ring is disposed at a junction of the inner edge of the annular peripheral plate and the cover body, so the heat sink structure has a double leakage-proof effect and prevents solder or flux for welding from causing a water block having different materials, so as to omit the condition of increase of the thermal resistance at the place of different materials to achieve the improvement of the cooling efficiency of the heat sink structure.

### BRIEF DESCRIPTION OF THE DRAWINGS

FIG. 1 is an exploded view of the water block of the disclosure;

FIG. 2 is another exploded view of the water block of the disclosure;

FIG. 3 is an exploded cross-sectional view of the water block of the disclosure;

FIG. 4 is a perspective assembled view of the water block of the disclosure;

FIG. 5 is an assembled cross-sectional view of the water block of the disclosure;

FIG. 6 is another assembled cross-sectional view of the water block of the disclosure; and

FIG. 7 is a schematic view of a using status of the water block of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

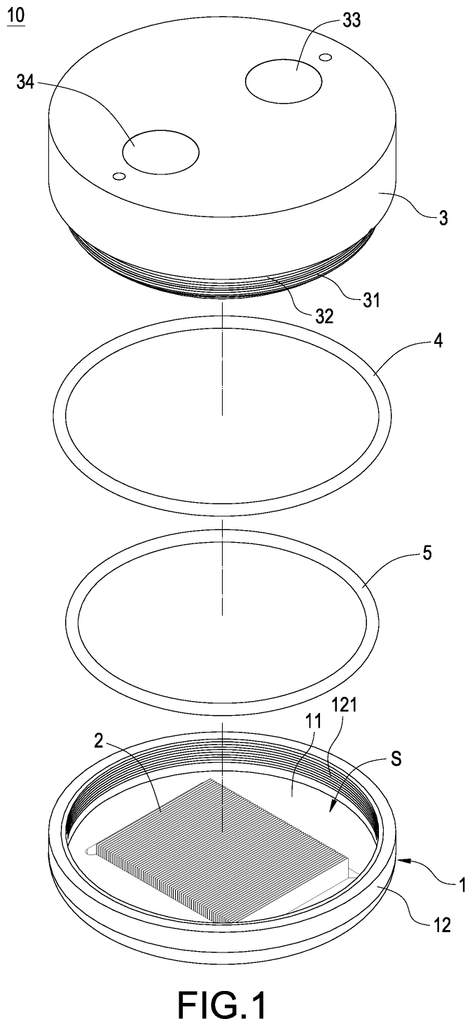

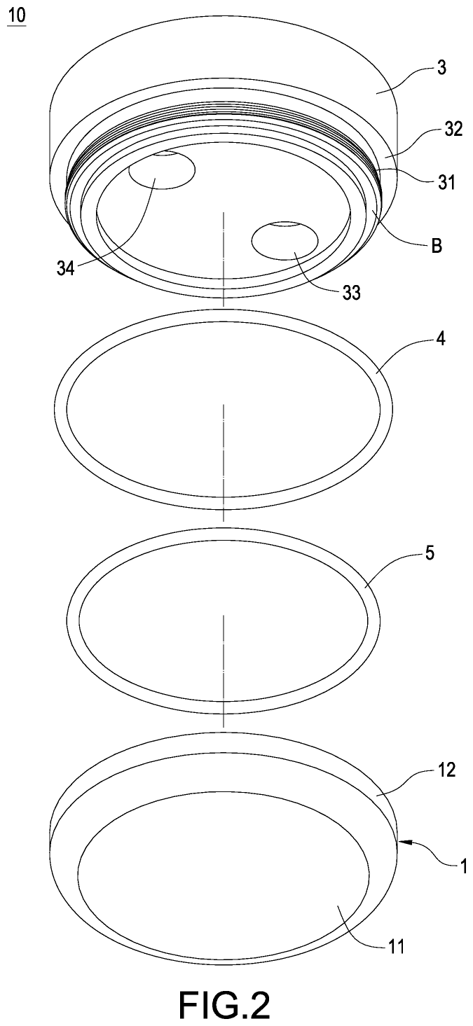

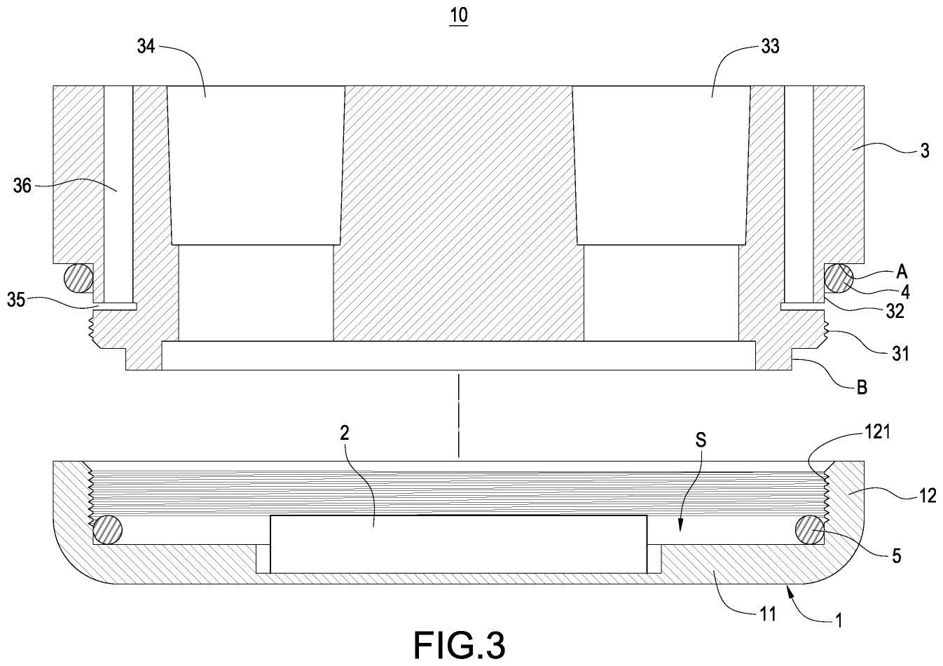

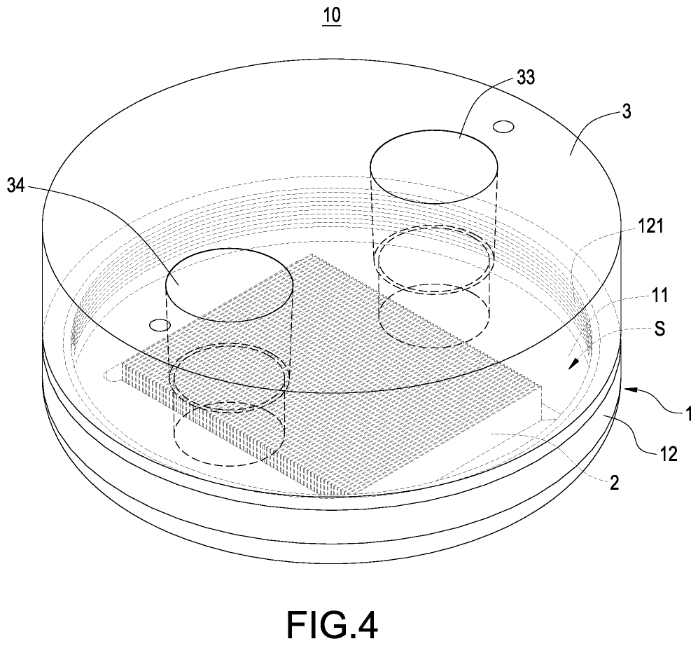

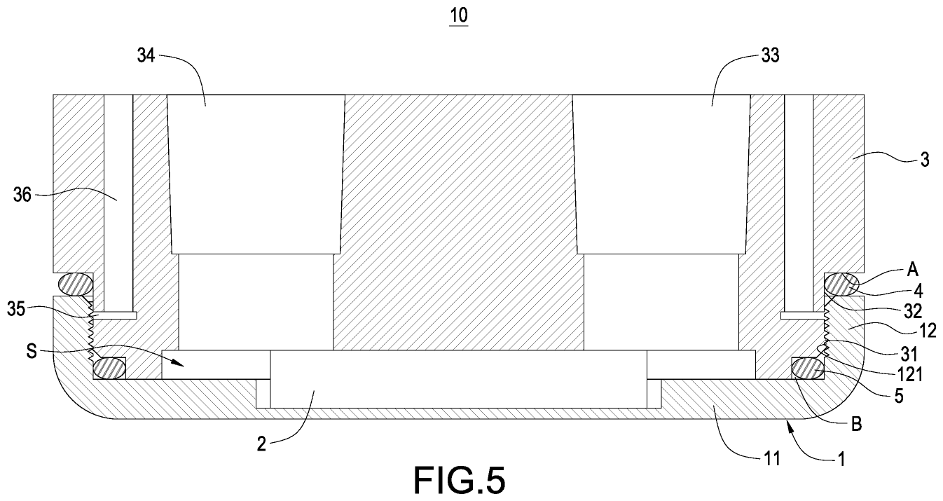

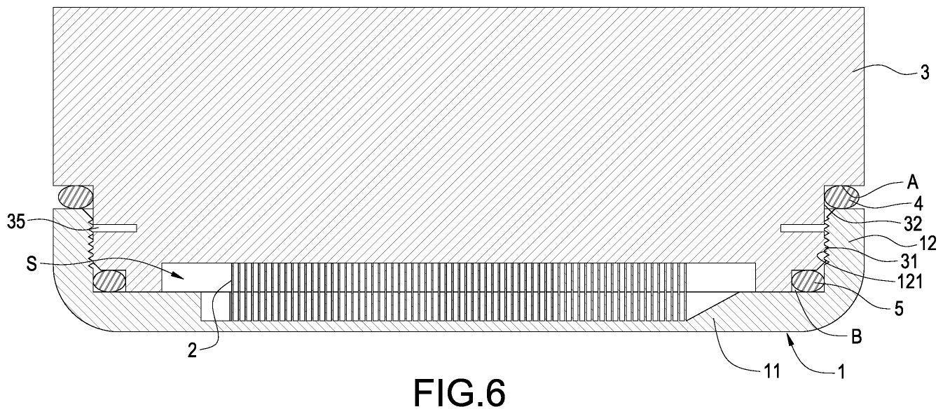

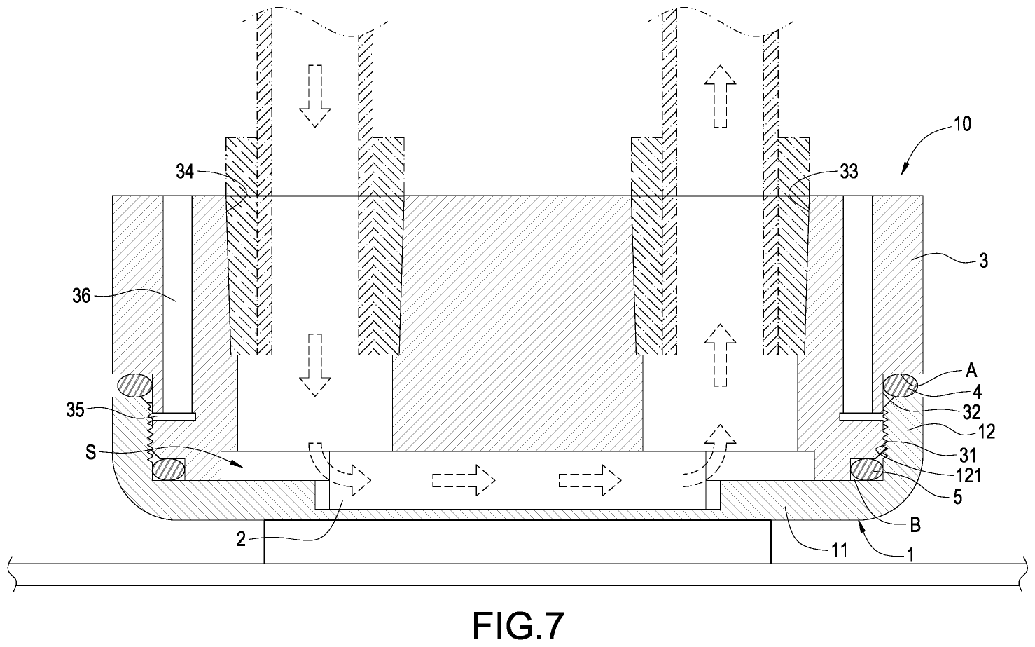

Please refer to FIGS. 1-7. The disclosure provides a heat sink structure. The heat sink structure 10 includes a seat 1, multiple fins 2 and a cover body 3.

As shown in FIGS. 1-7, the seat 1 includes a bottom plate 11 and an annular peripheral plate 12 upward extended from the bottom plate 11. An accommodation space S recessed on the seat 11 is enclosed by the bottom plate 11 and the annular peripheral plate 12. An inner wall of the annular peripheral plate 12 is disposed with an inner thread 121.

As shown in FIGS. 1 and 3-7, the multiple fins 2 are disposed in the accommodation space S. The multiple fins 2 are integrally formed from the bottom plate 11 by planing. That is, an upper surface of the bottom plate 11 is shoveled by a blade in order with planing to form the multiple fins 2 so as to let each fin 2 and the seat 1 be a component with an integral material.

As shown in FIGS. 1-7, the cover body 3 correspondingly covers the seat 1 and is screwed to the annular peripheral plate 12. The cover body 3 is disposed with an outer thread 31 screwed with the inner thread 121.

In detail, the cover body 3 is recessed to defined an annular notch 32 on an outer wall thereof and at a bottom periphery thereof. The annular peripheral plate 12 is embedded into the annular notch 32. The outer thread 31 is formed on an inner wall of the annular notch 32. A first groove A is formed between a top edge of the annular peripheral plate 12 and the inner wall of the annular notch 32. The inner wall of the annular notch 21 is recessed to form a second groove B at the bottom periphery of the cover body 3.

In addition, the top of the cover body 3 is disposed with an outlet opening 33 that can be connected to an outlet tube (not labeled in the figure) and an inlet opening 34 that can be connected to an inlet tube (not labeled in the figure). The inner wall of the annular notch 32 is recessed along a radial direction of the cover body 3 to form a first material escaping annular groove 35 extended along a peripheral direction of the cover body 3. The cover body 3 is recessed along an axial direction thereof to form a second material escaping annular groove 36 extended along the peripheral direction of the cover body 3. The outer thread 31 is disposed between the bottom periphery of the cover body 3 and the first material escaping annular groove 35, and the second material escaping annular groove 36 is disposed above the first material escaping annular groove 35.

As shown in FIGS. 1-3 and 5-7, the water block of the disclosure further includes a first O-ring 4 embedded into the first groove A is disposed at an outside of the annular peripheral plate 12 and clamped between the annular peripheral plate 12 and the cover body 3. That is, the first O-ring 4 is disposed at a junction of the annular peripheral plate 12 and the cover body 3, and at the outside of the annular peripheral plate 12.

As shown in FIGS. 1-3 and 5-7, the water block of the disclosure further includes a second O-ring 5 embedded into the second groove B and clamped between an inner edge of the annular peripheral plate 12 and the cover body 3. That is, the second O-ring 5 is disposed at a junction of the inner edge of the annular peripheral plate 12 and the cover body 3.

As shown in FIGS. 1-7, a using status of the heat sink structure 10 of the disclosure uses the cover body 3 correspondingly covering the seat 1 and screwed to the annular peripheral plate 12 to prevent solder or flux for welding from causing a water block having different materials, so as to omit the condition of increase of the thermal resistance at the place of different materials to achieve the improvement of the cooling efficiency of the heat sink structure 10.

In addition, the inner wall of the annular notch 32 may use slight deformation of the first material escaping annular groove 35 and the second material escaping annular groove 36 to let the inner thread 121 of the seat 1 and the outer thread 31 of the cover body 3 may be slightly deformed by the annular notch 32 to be screwed more tightly, and let the first O-ring 4 clamped between the annular peripheral plate 12 and the cover body 3 at the outside of the annular peripheral plate 12 more tightly, so as to achieve the improvement of the structural strength and leakage-proof effect of the heat sink structure 10.

Moreover, the first O-ring 4 is disposed at a junction of the annular peripheral plate 12 and the cover body 3, and at the outside of the annular peripheral plate 12. The second O-ring 5 is disposed at a junction of the inner edge of the annular peripheral plate 12 and the cover body 3, so the heat sink structure 10 has a double leakage-proof effect and prevents solder or flux for welding from causing a water block having different materials, so as to omit the condition of increase of the thermal resistance at the place of different materials to achieve the improvement of the cooling efficiency of the heat sink structure 10.

While this disclosure has been described by means of specific embodiments, numerous modifications and variations could be made thereto by those skilled in the art without departing from the scope and spirit of this disclosure set forth in the claims.

What is claimed is:

1. A heat sink structure comprising:
a seat, comprising a bottom plate and an annular peripheral plate upward extended from the bottom plate, an accommodation space recessed on the seat enclosed by the bottom plate and the annular peripheral plate;
multiple fins, disposed in the accommodation space; and
a cover body, correspondingly covering the seat, and screwed to the annular peripheral plate.

2. The heat sink structure of claim 1, wherein an inner thread is disposed on an inner wall of the annular peripheral plate, and an outer thread for screwing with the inner thread is disposed on the cover body.

3. The heat sink structure of claim 2, wherein the cover body is recessed to defined an annular notch on an outer wall thereof and at a bottom periphery thereof, the annular peripheral plate is embedded into the annular notch, and the outer thread is formed on an inner wall of the annular notch.

4. The heat sink structure of claim 3, wherein the inner wall of the annular notch is recessed along a radial direction of the cover body to forma first material escaping annular groove extended along a peripheral direction of the cover body, the cover body is recessed along an axial direction thereof to form a second material escaping annular groove extended along the peripheral direction and communicated with the first material escaping annular groove, the outer thread is disposed between the bottom periphery of the cover body and the first material escaping annular groove, and the second material escaping annular groove is disposed above the first material escaping annular groove.

5. The heat sink structure of claim 3, further comprising a first O-ring disposed at a junction of the annular peripheral plate and the cover body, and at an outside of the annular peripheral plate.

6. The heat sink structure of claim 5, wherein a first groove is defined between a top edge of the annular peripheral plate and the inner wall of the annular notch, and the first O-ring is embedded into the first groove and clamped between the annular peripheral plate and the cover body and at the outside of the annular peripheral plate.

7. The heat sink structure of claim 3, further comprising a second O-ring disposed at a junction of an inner edge of the annular peripheral plate and the cover body.

8. The heat sink structure of claim 7, wherein the inner wall of the annular notch is recessed to form a second groove at the bottom periphery of the cover body, the second O-ring is embedded into the second groove and clamped between the inner edge of the annular peripheral plate and the cover body.

9. The heat sink structure of claim 1, wherein the multiple fins and the bottom plate are integrally formed as one-piece form by planing.

10. The heat sink structure of claim 1, wherein a top of the cover body is disposed with an outlet opening and an inlet opening.
